(19) United States
(12) Patent Application Publication
(10) Pub. No.: US 2026/0343926 A1
(43) Pub. Date: Oct. 29, 2026

(54) SACRIFICIAL STRUCTURES SELECTIVELY PROTECTING LOWER NANOSTRUCTURES IN STACKED TRANSISTORS AND METHODS OF FORMING THE SAME

(71) Applicant: Taiwan Semiconductor Manufacturing Co., Ltd., Hsinchu (TW)

(72) Inventors: Yun Chen Teng, New Taipei City (TW); Sen-Hong Syue, Zhubei City (TW)

(21) Appl. No.: 19/737,718

(22) Filed: Jul. 10, 2026

Related U.S. Application Data
(63) Continuation of application No. 18/927,327, filed on Oct. 25, 2024.

(51) Int. Cl. H10D 30/43; H10D 30/01; H10D 30/67; H10D 62/10; H10D 64/01

(52) U.S. Cl. CPC H10D 30/43; H10D 30/014; H10D 30/6713; H10D 30/6735; H10D 30/6757; H10D 62/121; H10D 64/017; H10D 64/018

(57) ABSTRACT

A semiconductor device and the method of forming the same are provided. The semiconductor device may include a first nanostructure, a first gate structure wrapping around the first nanostructure, a first inner spacer on the first nanostructure and the first gate structure, a first source/drain region on the first nanostructure and the first inner spacer, a second nanostructure underneath the first nanostructure, a second gate structure wrapping around the second nanostructure, a second inner spacer on the second nanostructure and the second gate structure, and a second source/drain region on the second nanostructure and the second inner spacer. The first inner spacer may have a first outer sidewall with a first width. The second inner spacer may have a second outer sidewall with a second width smaller than the first width.

### PRIORITY CLAIM AND CROSS-REFERENCE

This application is a continuation of U.S. Patent Application No. 18/927,327, filed on Oct. 25, 2024, which application is incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example a stacking transistor in accordance with some embodiments.

FIGS. 2, 3, 4, 5, 6, 7, 8, 9, 10, 11, 12, and 13 are various views of intermediate steps in the manufacturing of a stacking transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide semiconductor devices and methods of forming the same. The semiconductor devices may include a stacking transistor comprising upper transistors and lower transistors. The upper transistors and the lower transistors may be of different device types (e.g., n-type and p-type). The upper transistors may comprise upper semiconductor nanostructures as channel regions and the lower transistors may comprise lower semiconductor nanostructures as channel regions. By forming different materials on the upper semiconductor nanostructures and on the lower semiconductor nanostructures, different stress (and the corresponding strain) may be induced in the upper semiconductor nanostructures and in the lower semiconductor nanostructures. As a result, the overall performance of the stacking transistor may be improved.

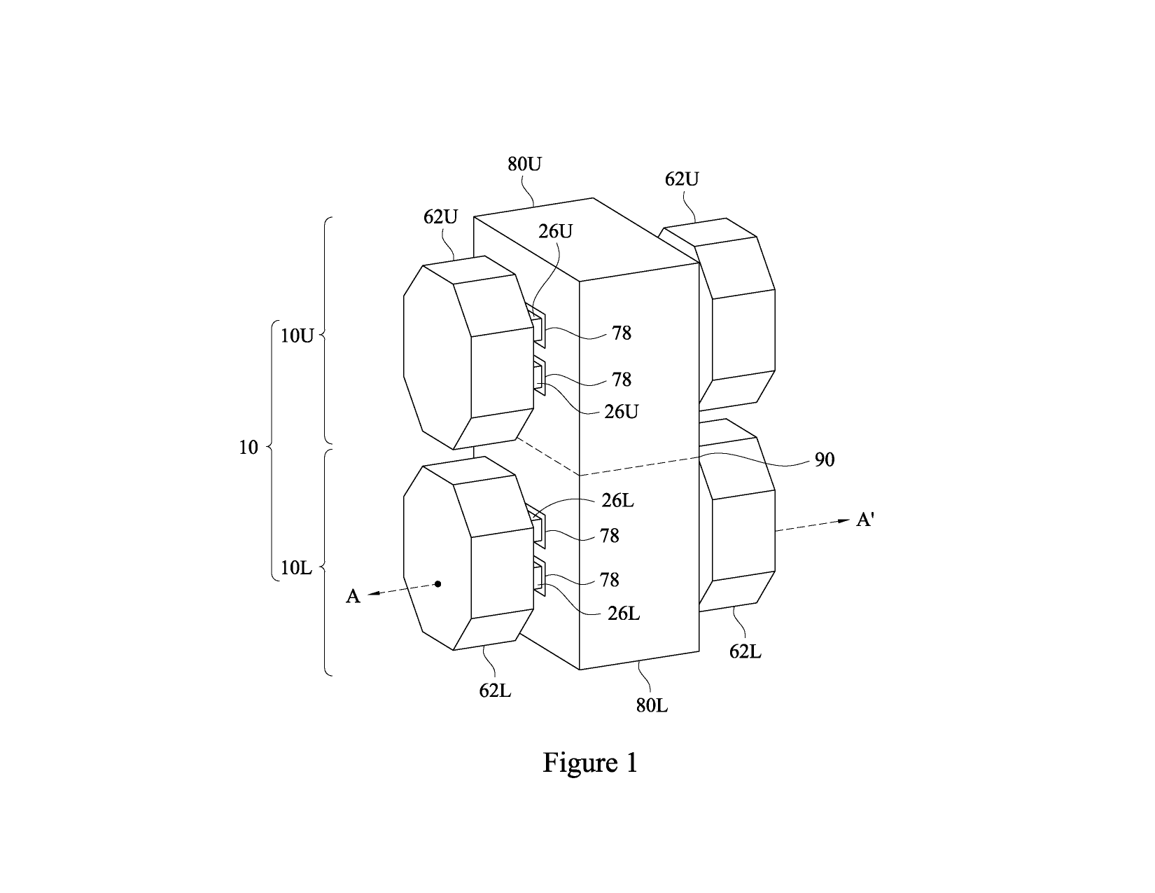

FIG. 1 illustrates an example of a stacking transistor 10 (including Field Effect Transistors (FETs) 10U and 10L) in accordance with some embodiments. FIG. 1 is a perspective view, and some features of the stacking transistor are omitted for illustration clarity. The stacking transistor includes multiple vertically stacked FETs. For example, a stacking transistor may include a lower nanostructure-FET 10L of a first device type (e.g., n-type or p-type) and an upper nanostructure-FET 10U of a second device type (e.g., p-type or n-type). When the stacking transistor is a Complementary Field-Effect Transistors (CFET), the second device type of the upper nanostructure-FET 10U is opposite to the first device type of the lower nanostructure-FET 10L. The upper nanostructure-FETs 10U and lower nanostructure-FET 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors, Nano Field-effect Transistors (nano-FET), Fin Field Effect Transistors finFETs, or the like.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower epitaxial source/drain regions 62L and upper epitaxial source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate selected ones of the source/drain regions 62 and/or selected ones of the gate electrodes 80.

FIG. 1 further illustrates reference cross-section A-A', which is a vertical cross-section that is parallel to a longitudinal axis of the semiconductor nanostructures 26 of a stacking transistor and in a direction of, for example, a current flow between the source/drain regions 62 of the stacking transistor. Subsequent figures may refer to reference cross-section A-A' for clarity.

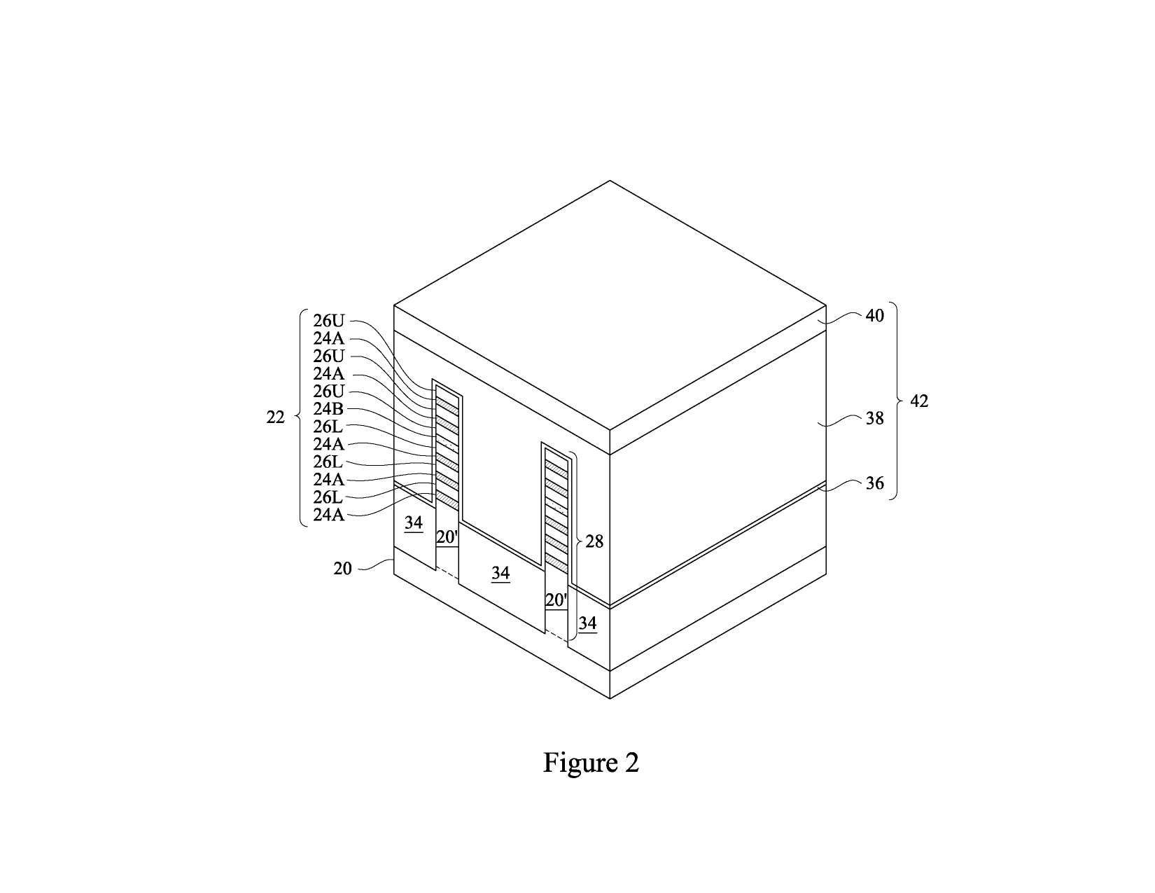

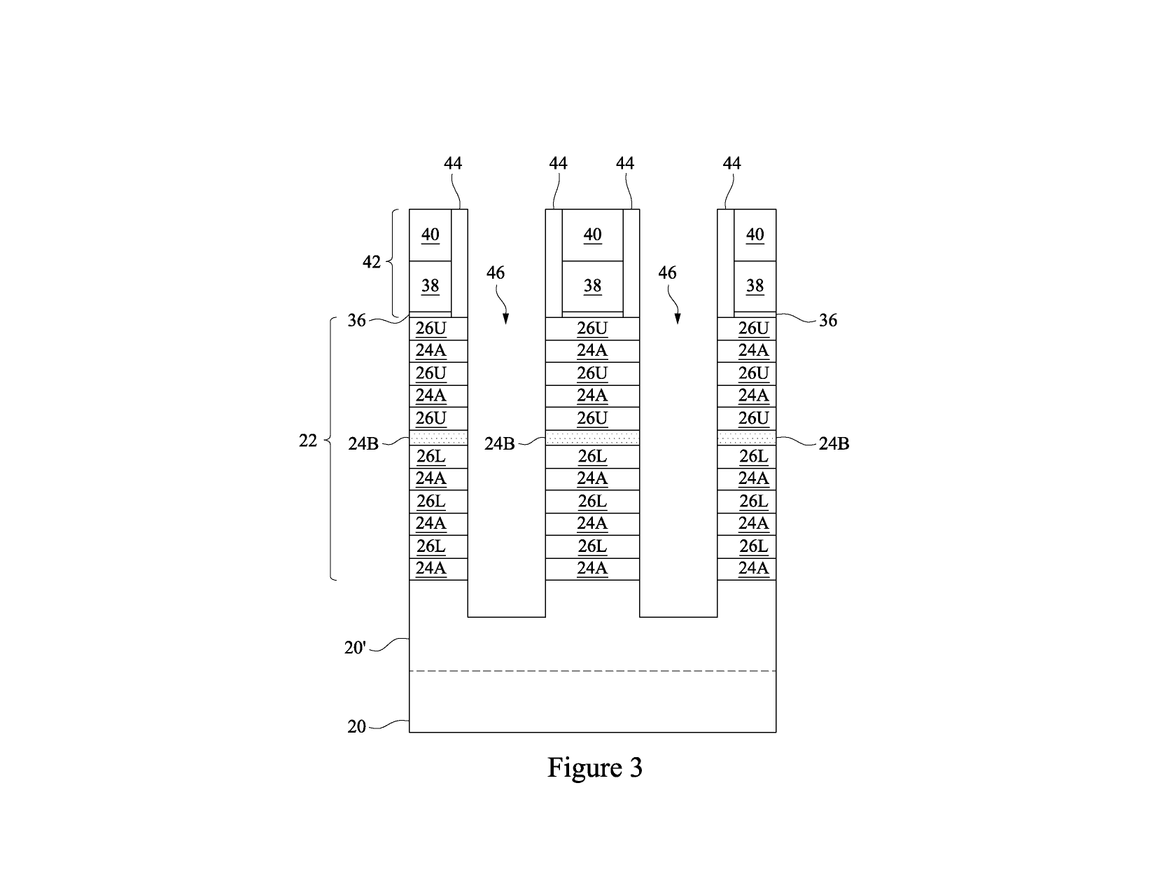

FIGS. 2 through 13 are various views of intermediate steps in the manufacturing of a stacking transistor, which is similar to the one shown in FIG. 1, in accordance with some embodiments. FIG. 2 is a perspective view and FIGS. 3 through 13 are cross-sectional views of the structure shown in FIG. 2 along a reference cross-section similar to the reference cross-section A-A' as shown in FIG. 1.

In FIG. 2, a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the substrate 20. Each of semiconductor strips 28 includes semiconductor fin 20’ (patterned portions of the substrate 20) and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. The dummy nanostructures 24A and the dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy nanostructures 24B may be removed at a faster rate than the dummy nanostructures 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent process steps without significantly removing the semiconductor nanostructures 26. In some embodiments, the dummy nanostructures 24A are formed of or comprise silicon germanium, the semiconductor nanostructures 26 are formed of silicon, and the dummy nanostructures 24B may be formed of germanium or silicon germanium with a higher germanium atomic percentage than the dummy nanostructures 24A.

The lower semiconductor nanostructures 26L will act as channel regions for lower nanostructure-FETs of the stacking transistor. The upper semiconductor nanostructures 26U will act as channel regions for upper nanostructure-FETs of the stacking transistor. The semiconductor nanostructures 26 that are immediately above/below (e.g., in contact with) the dummy nanostructures 24B may be used for isolation and may or may not act as channel regions for the stacking transistor. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the substrate 20 to define the semiconductor strips 28, which includes the semiconductor fins 20’, the dummy nanostructures 24, and the semiconductor nanostructures 26.

For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, STI regions 34 are formed over the substrate 20 and between adjacent semiconductor strips 28. STI regions 34 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 34 may include depositing the dielectric layer(s), and performing a planarization process such as a Chemical Mechanical Polishing (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 34 include silicon oxide formed by an FCVD process, followed by an anneal process. Then, the dielectric layers(s) are recessed to define the STI regions 34. The dielectric layer(s) maybe recessed such that upper portions of semiconductor strips 28 (including multi-layer stacks 22) protrude higher than the remaining STI regions 34.

After the STI regions 34 are formed, dummy gate stacks 42 may be formed over and along sidewalls of the upper portions of the semiconductor strips 28 (the portions that protrude higher than the STI regions 34). Forming the dummy gate stacks 42 may include forming dummy dielectric layer 36 on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22 and into the semiconductor fins 20’. The bottom surfaces of the source/drain recesses 46 may be at a level above, below, or level with the top surfaces of the STI regions 34. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon the source/drain recesses 46 reaching a selected depth.

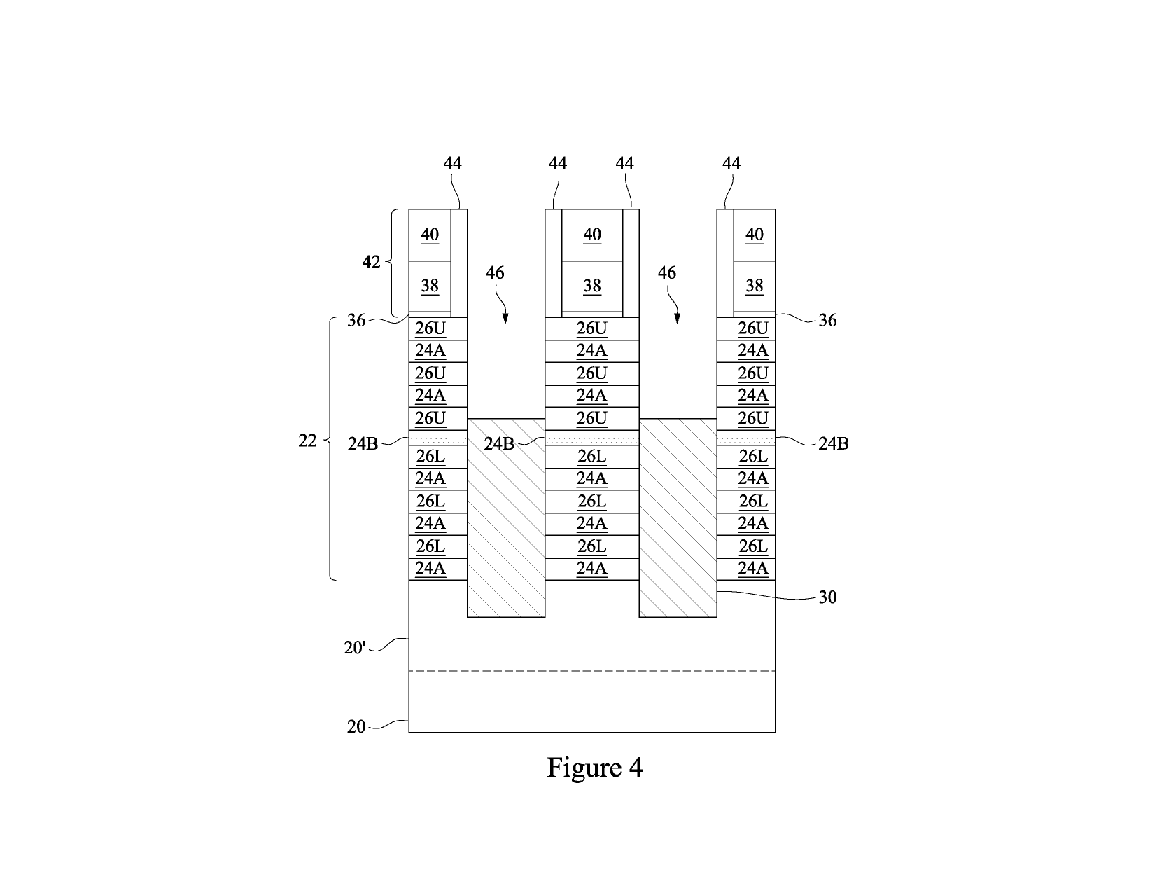

In FIG. 4, a dielectric layer 30 is formed in the source/drain recesses 46. The dielectric layer 30 may fill up lower portions of the source/drain recesses 46 and may cover sidewalls of the lower semiconductor nanostructures 26L and sidewalls of the dummy nanostructures 24A in contact with the lower semiconductor nanostructures 26L (e.g., the dummy nanostructures 24A between the dummy nanostructures 24B and the semiconductor fins 20’). Sidewalls of the dummy nanostructures 24A in contact with the upper semiconductor nanostructures 26U (e.g., the dummy nanostructures 24A between the dummy nanostructures 24B and the dummy gate stacks 42) may be exposed after forming the dielectric layer 30. The dielectric layer 30 may be used to protect the dummy nanostructures 24A during a subsequent etching process. In some embodiments, sidewalls of the upper semiconductor nanostructures 26U in contact with the dummy nanostructures 24B are in contact with the dielectric layer 30. The dielectric layer 30 may be removed in a subsequent process and may be referred to as a sacrificial layer. Although the dielectric layer 30 is illustrated as having a flat top surface in FIG. 4, in other embodiments, the dielectric layer 30 may have a curved top surface, such as a concave top surface or a convex top surface.

The dielectric layer 30 may comprise a dielectric material, such as silicon oxide, silicon nitride, silicon carbide, silicon oxynitride, silicon oxycarbide, silicon carbonitride, silicon oxycarbonitride, or the like. A formation of the dielectric layer 30 may include a suitable deposition process, such as CVD, FCVD, or the like. In the embodiments where FCVD is used, the formation of the dielectric layer 30 comprises a deposition step, a curing step, and an annealing step. In the deposition step, precursors, such as tri-silylamine, ammonia, oxygen may be used. The deposited film may comprise elements, such as silicon, oxygen, carbon, hydrogen, nitrogen, and the like. The weight ratio of oxygen in the deposited film may be in a range from about 0% to about 90 %. The weight ratio of carbon in the deposited film may be in a range from about 0% to about 90 %. The weight ratio of hydrogen in the deposited film may be in a range from about 0% to about 90 %. The weight ratio of nitrogen in the deposited film may be in a range from about 0% to about 90 %. Then, the deposited film may be densified by a curing step under ozone or ultra-violet radiation for a duration smaller or equal to about 180 seconds.

The annealing step may follow the curing step, and may be a single annealing process or a double annealing process. The single annealing process may be a dry annealing process. During the dry annealing process of the single annealing process, the deposited film may be annealed under an environment of inert gas (e.g., nitrogen, helium, argon) for a duration in a range from about 1 minute to about 48 hours. The annealing temperature may be in a range from about 25˚C to about 800˚C and annealing pressure may be in a range from about 0.01 atm to about 25 atm. In the embodiments where the single annealing process is performed, the dielectric layer 30 may comprise a nitrogen-containing dielectric material, such as silicon nitride, silicon oxynitride, silicon carbonitride, silicon oxycarbonitride, or the like.

The double annealing process may include a wet annealing process followed by a dry annealing process. During the wet annealing process of the double annealing process, the deposited film may be annealed under an environment of water steam, hydrogen peroxide steam, oxygen, free radicals generated by water, hydrogen peroxide, and oxygen, and combinations thereof. Nitrogen may be also used as a carrier gas. The weight ratio of water steam in the wet annealing environment may be in a range from about 5% to about 100 %. The annealing temperature may be in a range from about 25˚C to about 800˚C and annealing pressure may be in a range from about 0.01 atm to about 25 atm. During the dry annealing process of the double annealing process, the deposited film may be annealed under an environment oxygen, nitrogen, or the like for a duration in a range from about 1 minute to about 48 hours. The annealing temperature may be in a range from about 25˚C to about 800˚C and annealing pressure may be in a range from about 0.01 atm to about 25 atm. In the embodiments where the double annealing process is performed, the dielectric layer 30 may comprise an oxygen-containing dielectric material, such as silicon oxide, silicon oxynitride, silicon oxycarbide, silicon oxycarbonitride, or the like.

In some embodiments, the dielectric material of the dielectric layer 30 may also form on other surfaces in the source/drain recesses 46, such as sidewalls of the upper semiconductor nanostructures 26U, the dummy nanostructures 24A in contact with the upper semiconductor nanostructures 26U, and the gate spacers 44 during the deposition step. In such embodiments, an etching step may follow the annealing step to remove the dielectric material of the dielectric layer 30 from said surfaces. The etching step may include an isotropic etching process or the like.

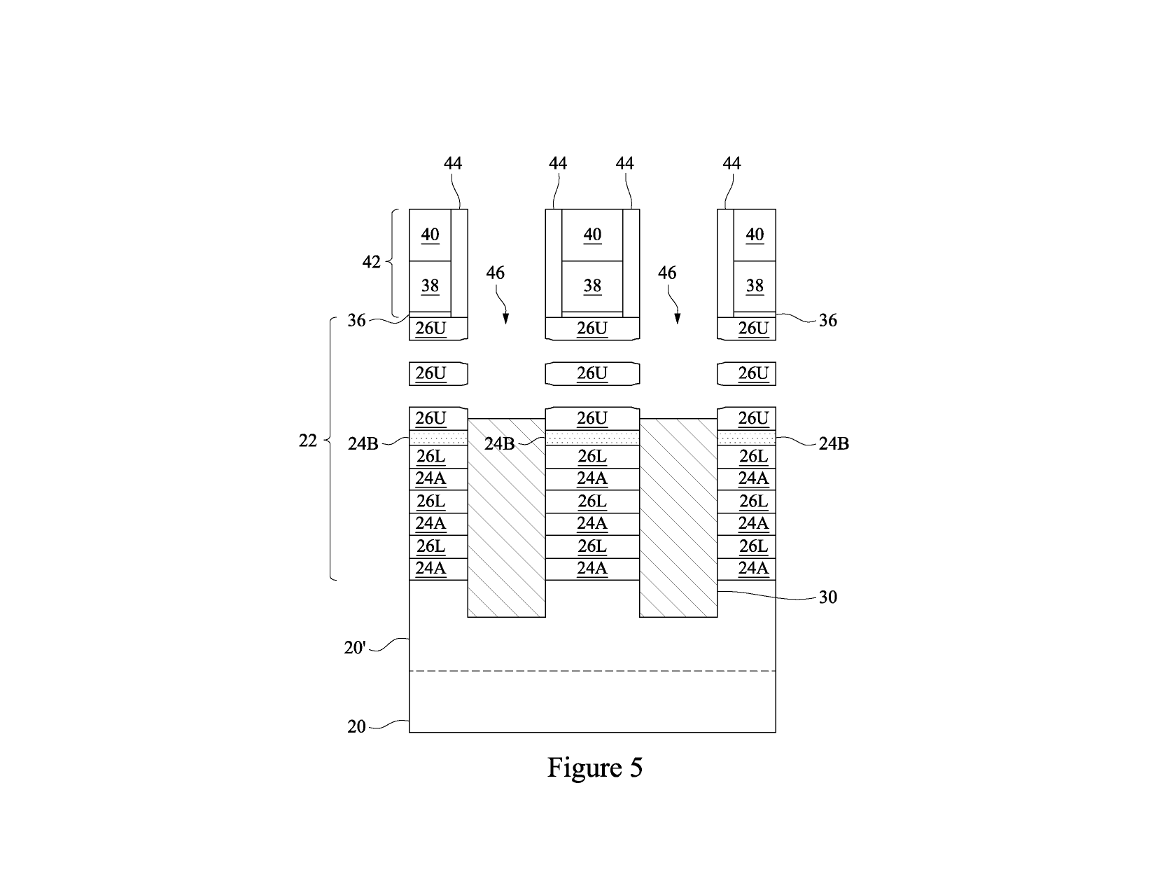

In FIG. 5, the dummy nanostructures 24A in contact with the upper semiconductor nanostructures 26U are removed, while the dummy nanostructures 24A in contact with the lower semiconductor nanostructures 26L remain intact, which may be due to the protection provided by the dielectric layer 30. The dummy nanostructures 24A in contact with the upper semiconductor nanostructures 26U may be removed by a suitable etching process, such as an isotropic etching process. The etching process may selectively remove the material of the dummy nanostructures 24A without significantly removing the materials of the upper semiconductor nanostructures 26U or the dielectric layer 30. In some embodiments, the upper semiconductor nanostructures 26U may be slightly etched such spacing between the upper semiconductor nanostructures 26U is greater than spacing between the lower semiconductor nanostructures 26L. In the embodiments where the dummy nanostructures 24A comprise silicon germanium and the upper semiconductor nanostructures 26U include silicon, the etching process may be a drying etching process and etchants such as tetramethylammonium hydroxide, ammonium hydroxide, or the like may be used.

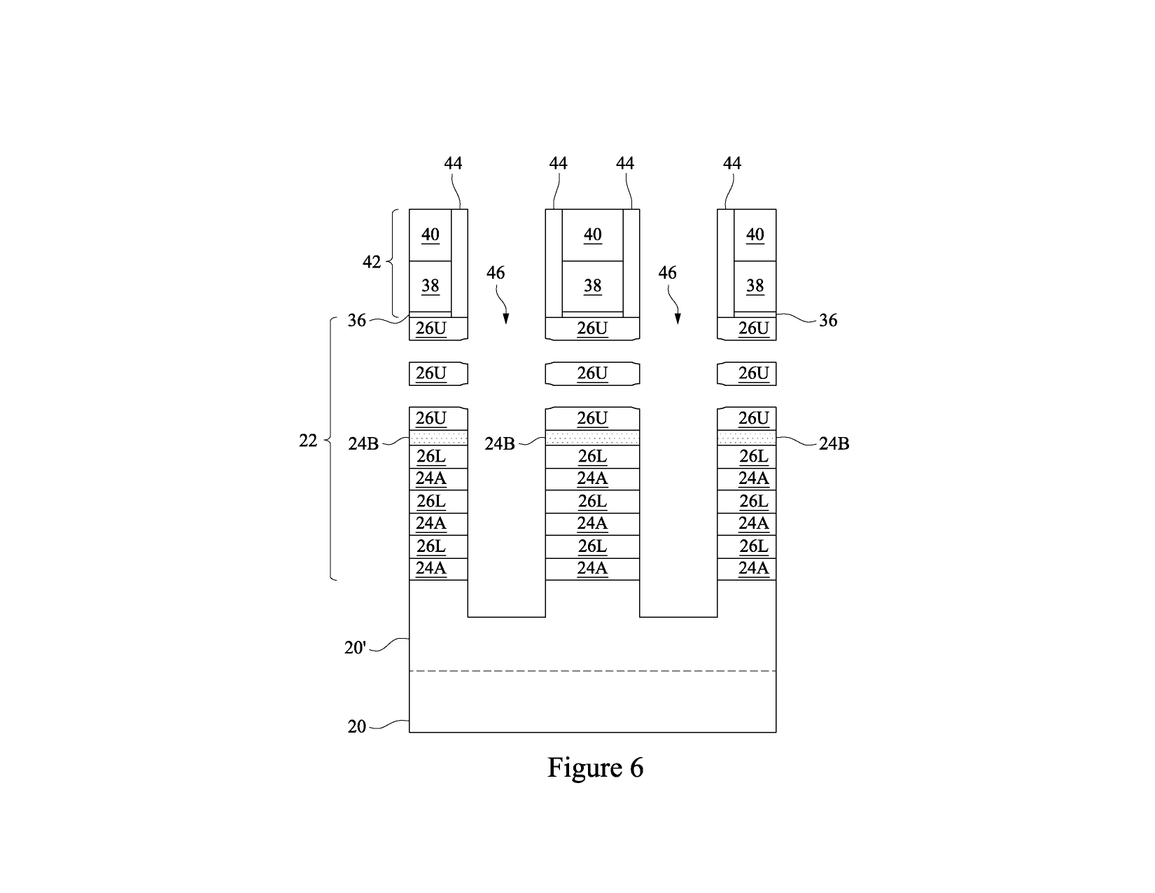

In FIG. 6, the dielectric layer 30 is removed to expose the sidewalls of the lower semiconductor nanostructures 26L and the sidewalls of the dummy nanostructures 24A in contact with the lower semiconductor nanostructures 26L. The dielectric layer 30 may be removed by a suitable etching process. The etching process may selectively remove the material of the dielectric layer 30 without significantly removing the materials of the upper semiconductor nanostructures 26U, the lower semiconductor nanostructures 26L, the dummy nanostructures 24A, the dummy nanostructures 24B, or the semiconductor fins 20’. In some embodiments, the etching process is a wet etching process using etchant(s), such as hydrofluoric acid, and/or the like. In some embodiments, the etching process is a dry etching process using etchant(s), such as hydrofluoric acid, ammonia, and/or the like.

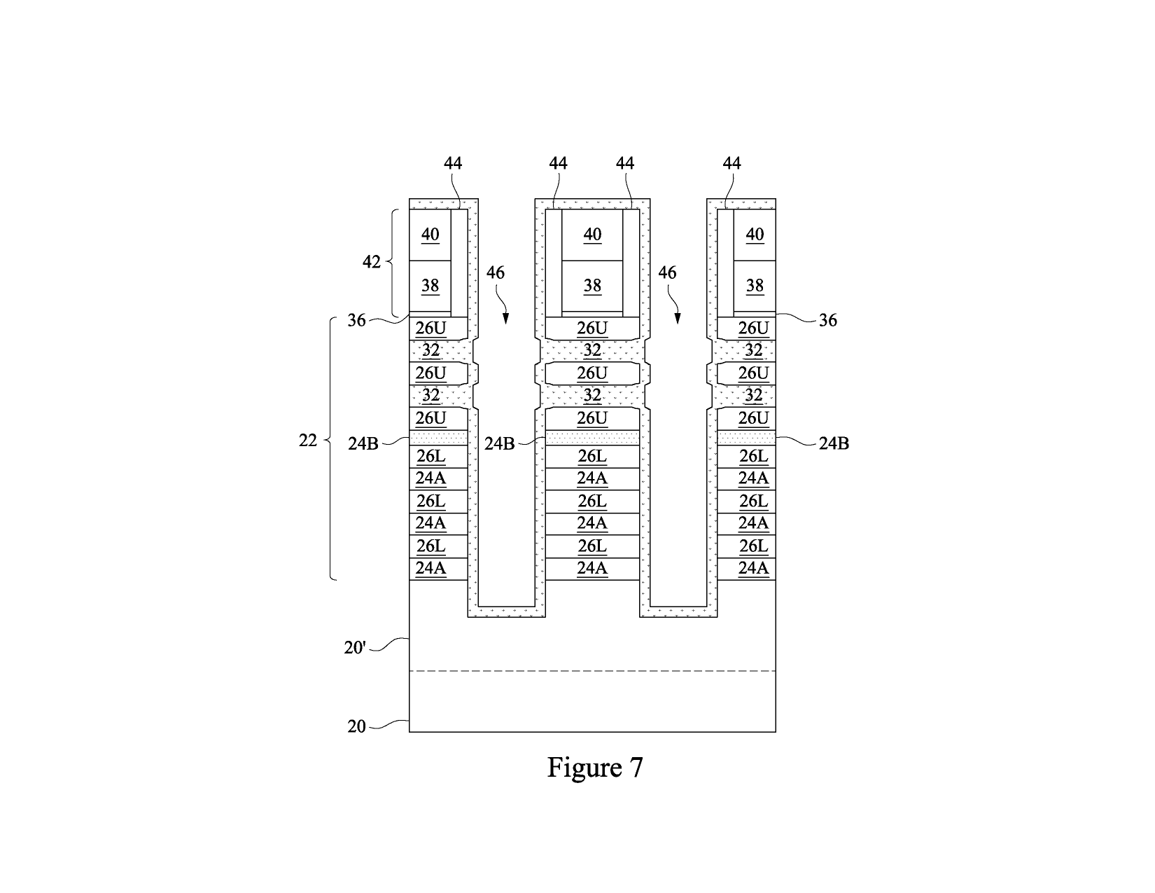

In FIG. 7, sacrificial layers 32 may be formed in the source/drain recesses 46 to occupy spaces the dummy nanostructures 24A occupied before being removed. The sacrificial layers 32 may be in contact with the upper semiconductor nanostructures 26U and may also cover sidewalls of other features in the source/drain recesses 46. The sacrificial layers 32 may be deposited by a suitable deposition process, such as CVD, ALD, or the like. The sacrificial layers 87 layer may comprise an insulating material, such as silicon oxide, silicon nitride, silicon oxycarbide, or the like. The sacrificial layers 32 may comprise a different material from the dummy nanostructures 24A in contact with the lower semiconductor nanostructures 26L. Therefore, the stress (and the corresponding strain) the sacrificial layers 32 may induce in the upper semiconductor nanostructures 26U may be different from the stress (and the corresponding strain) the dummy nanostructures 24A may induce in the lower semiconductor nanostructures 26L. Since the upper semiconductor nanostructures 26U may act as the channel regions of the upper nanostructure-FETs of the stacking transistor and the lower semiconductor nanostructures 26L may act as the channel regions for the lower nanostructure-FETs of the stacking transistor, different stress (and the corresponding strain) in the upper semiconductor nanostructures 26U and the lower semiconductor nanostructures 26L may improve the overall performance of the stacking transistor.

In the embodiments where the stacking transistor is a CFET, which includes the upper nanostructure-FETs as p-type devices and the lower nanostructure-FETs as n-type devices, the sacrificial layers 32 may induce compressive stress and strain in the upper semiconductor nanostructures 26U and the dummy nanostructures 24A may induce tensile stress and strain in the lower semiconductor nanostructures 26L. In the embodiments where the stacking transistor is a CFET, which includes the upper nanostructure-FETs as n-type devices and the lower nanostructure-FETs as p-type devices, the sacrificial layers 32 may induce tensile stress and strain in the upper semiconductor nanostructures 26U and the dummy nanostructures 24A may induce compressive stress and strain in the lower semiconductor nanostructures 26L.

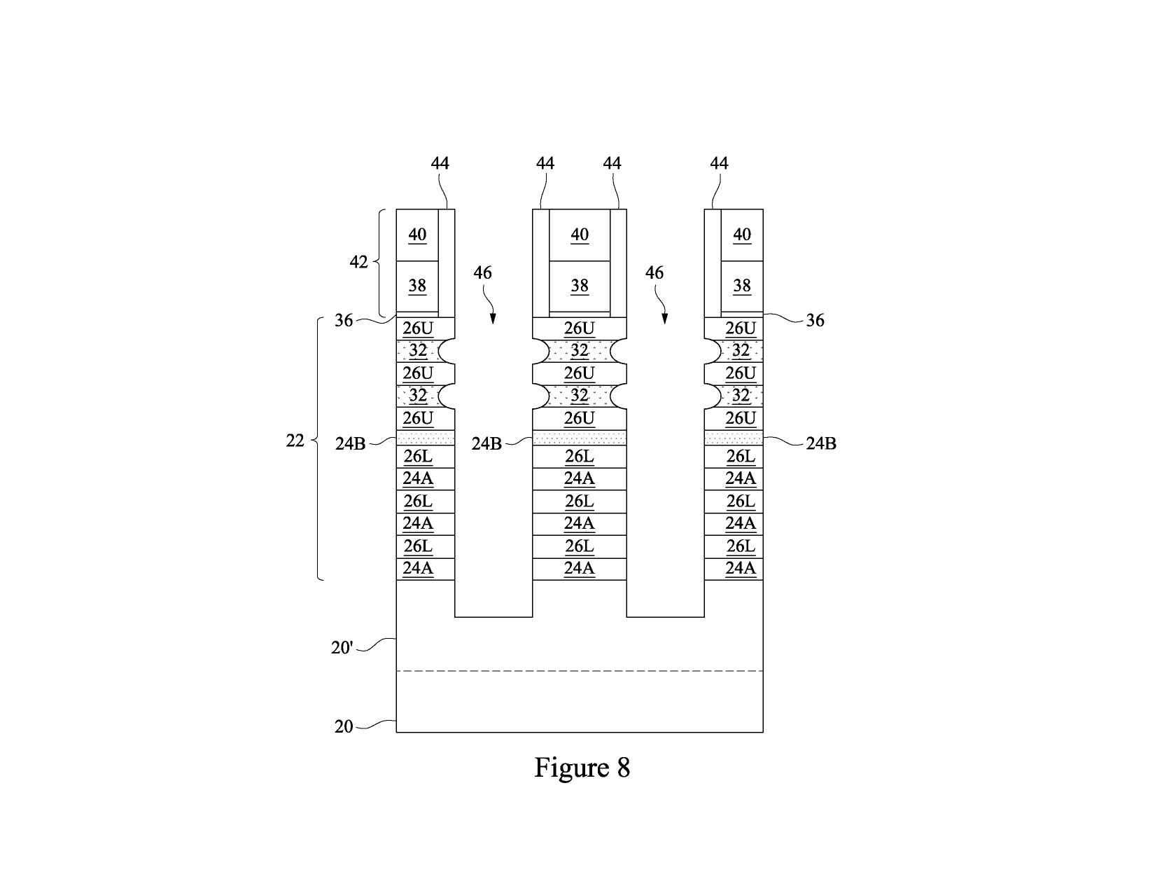

In FIG. 8, the sacrificial layers 32 are partially removed, after which sidewalls of the sacrificial layers 32 are recessed from sidewalls of the upper semiconductor nanostructures 26U. Portions of the sacrificial layers 32 that cover the sidewalls of other features in the source/drain recesses 46 may also be removed. The sidewalls of the sacrificial layers 32 may be concave after the partial removal of the sacrificial layers 32. The sacrificial layers 32 may be partially removed by a suitable etching process. The etching process may selectively remove the material of the sacrificial layers 32 without significantly removing the materials of the upper semiconductor nanostructures 26U, the lower semiconductor nanostructures 26L, the dummy nanostructures 24A, the dummy nanostructures 24B, or the semiconductor fins 20’. The etching process may be a dry etching process using etchant(s), such as hydrofluoric acid, ammonia, and/or the like.

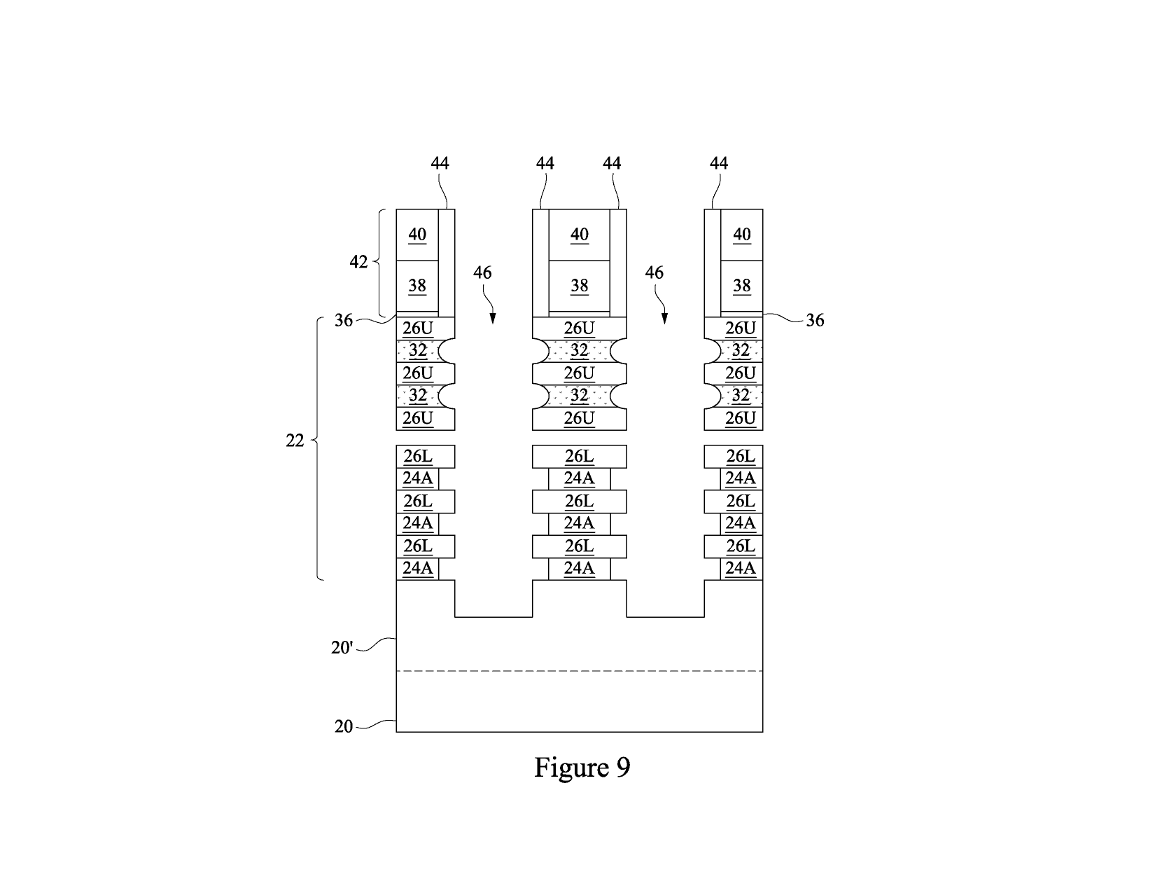

In FIG. 9, the dummy nanostructures 24A in contact with the lower semiconductor nanostructures 26L are partially removed and the dummy nanostructure 24B are completely removed, after which sidewalls of the dummy nanostructures 24A are recessed from sidewalls of lower semiconductor nanostructures 26L. In some embodiments, the sidewalls of the dummy nanostructures 24A are substantially straight after the partial removal of the dummy nanostructures 24A. In some embodiments, the sidewalls of the dummy nanostructures 24A are curved after the partial removal of the dummy nanostructures 24A. The dummy nanostructures 24A and the dummy nanostructure 24B may be removed by a suitable etching process. The etching process may selectively remove the materials of the dummy nanostructures 24A and the dummy nanostructure 24B without significantly removing the materials of the upper semiconductor nanostructures 26U, the lower semiconductor nanostructures 26L, or the semiconductor fins 20’. The etching process may remove the dummy nanostructures 24A at a slower rate than the dummy nanostructure 24B. In the embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etching process may be a dry etching process using etchant(s), such as chlorine, and/or the like. Because the dummy gate stacks 42 warp around the sidewalls of the semiconductor nanostructures 26 (see FIG. 2), the dummy gate stacks 42 may support the upper semiconductor nanostructures 26U so that the upper semiconductor nanostructures 26U do not collapse upon the complete removal of the dummy nanostructures 24B.

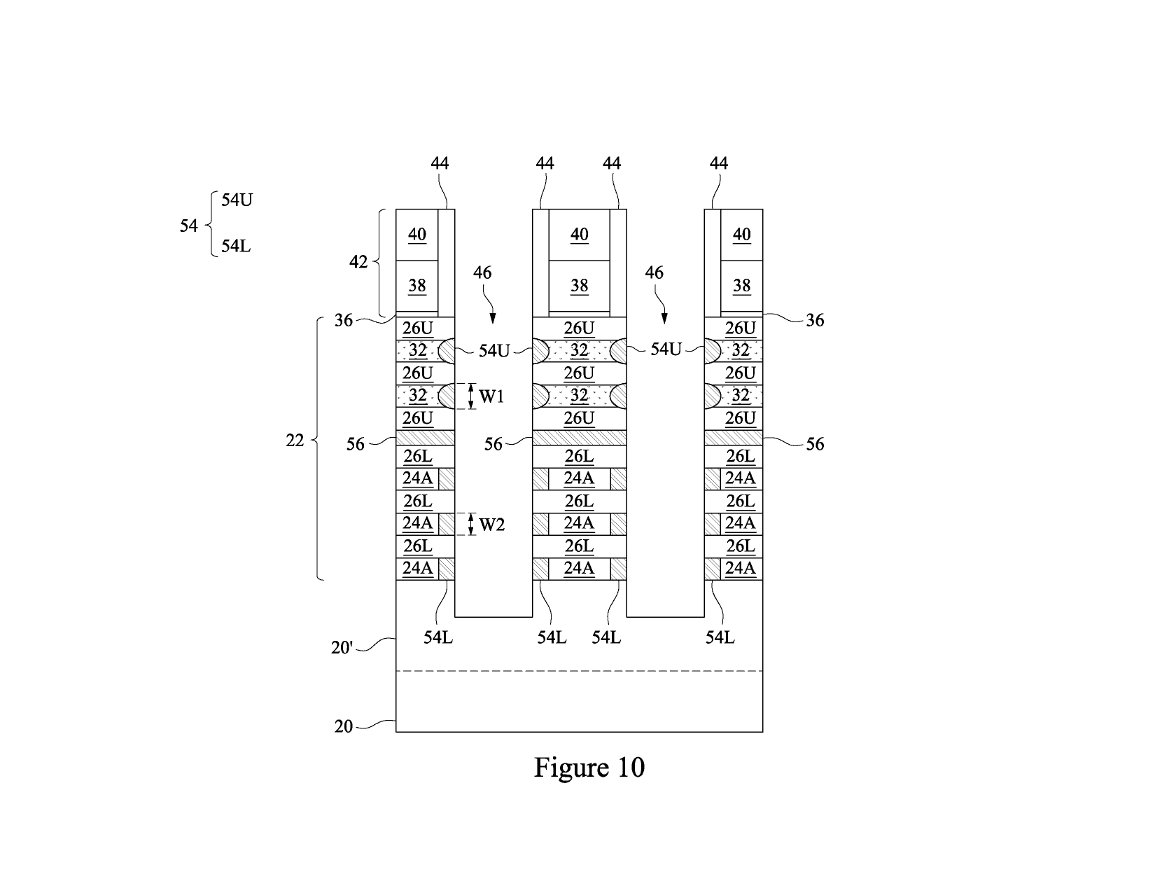

In FIG. 10, inner spacers 54 and dielectric isolation layers 56 are formed. The inner spacers 54 may include upper inner spacers 54U formed on the sidewalls of the sacrificial layers 32 and lower inner spacers 54L formed on the sidewalls of the dummy nanostructures 24A. The upper inner spacers 54U may have convex inner sidewalls in contact with the concave sidewalls of the sacrificial layers 32. The inner sidewalls of the upper inner spacers 54U may have a first curvature. The upper inner spacers 54U may have outer sidewalls with a first width W1. The outer sidewalls of the upper inner spacers 54U may be covered by epitaxial source/drain regions in a subsequent process. The lower inner spacers 54L may have substantially straight inner sidewalls in contact with the substantially straight sidewalls of the dummy nanostructures 24A or curved inner sidewalls in contact with the curved sidewalls of the dummy nanostructures 24A. The inner sidewalls of the lower inner spacers 54L may have a second curvature smaller than the first curvature of the inner sidewalls of the upper inner spacers 54U. The lower inner spacers 54L may have outer sidewalls with a second width W2 smaller than the first width W1. The outer sidewalls of the lower inner spacers 54L may be covered by epitaxial source/drain regions in a subsequent process.

The dielectric isolation layers 56 may be formed in spaces the dummy nanostructures 24B occupied before being removed. As described in greater details later, source/drain regions may be subsequently formed in the source/drain recesses 46, and the dummy nanostructures 24A may be replaced with corresponding gate structures. The inner spacers 54 may be used to isolate the subsequently formed source/drain regions from the subsequently formed gate structures. The dielectric isolation layers 56 may be used to isolate the upper semiconductor nanostructures 26U from the lower semiconductor nanostructures 26L.

The inner spacers 54 and the dielectric isolation layers 56 may be formed by conformally depositing a suitable dielectric material in the source/drain recesses 46, on sidewalls of the sacrificial layers 32 and the dummy nanostructures 24A, and between the bottom upper semiconductor nanostructures 26U and the top lower semiconductor nanostructures 26L. The dielectric material may be then etch to remove excess portions. The dielectric material may be a hard dielectric material, such as a carbon-containing dielectric material, such as silicon oxycarbonitride, silicon oxycarbide, silicon carbonitride, or the like. Other low-dielectric constant (low-k) materials having a k-value less than about 3.5 may be utilized. The dielectric material may be formed by a suitable deposition process, such as ALD, CVD, or the like. The etching of the dielectric material may be an anisotropic etching process or an isotropic etching process.

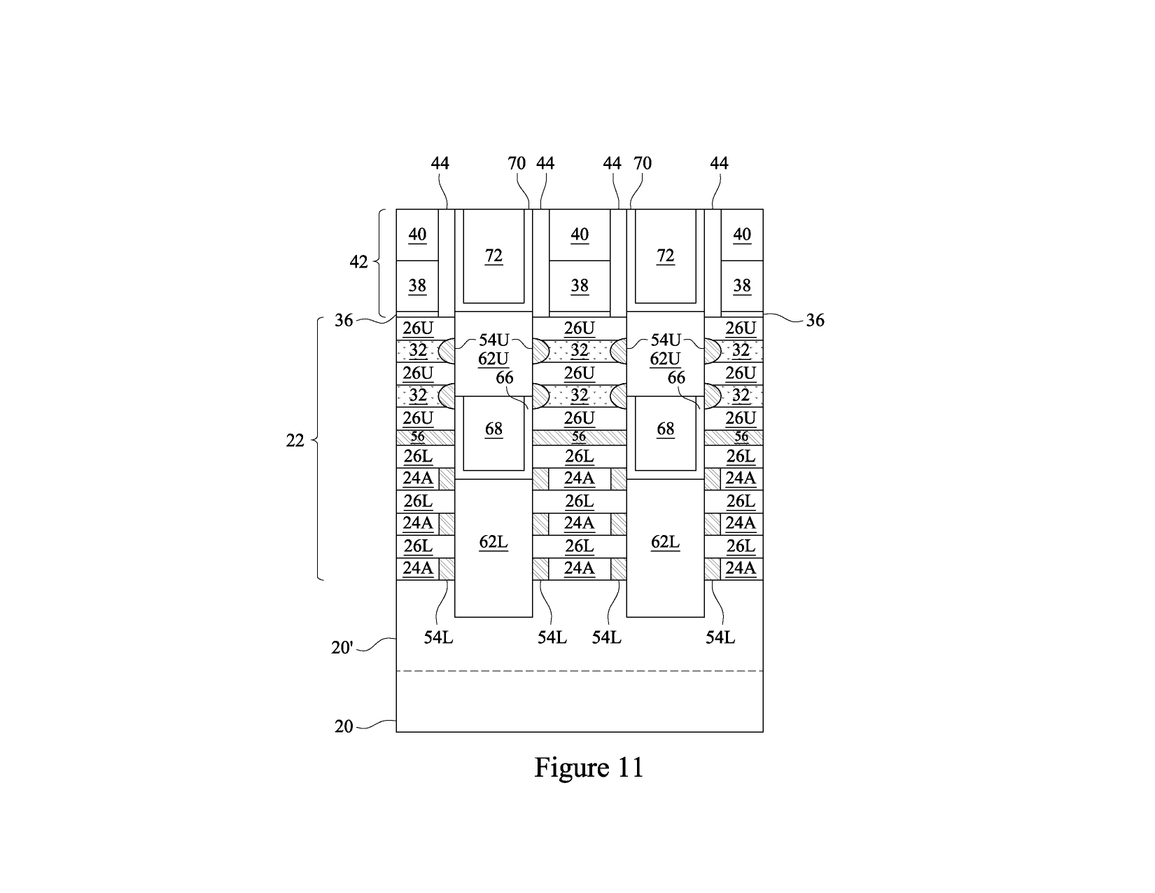

In FIG. 11, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. The upper epitaxial source/drain regions 62U are in contact with the upper semiconductor nanostructures 26U and are not in contact with the lower semiconductor nanostructures 26L. The lower epitaxial source/drain regions 62L are in contact with the lower inner spacers 54L, which electrically insulate the lower epitaxial source/drain regions 62L from the dummy nanostructures 24A. The upper epitaxial source/drain regions 62U are in contact with the upper inner spacers 54U, which electrically insulate the upper epitaxial source/drain regions 62U from the dummy nanostructures 24A. The dummy nanostructures 24A will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower epitaxial source/drain regions 62L, depending on the selected conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant. Adjacent upper epitaxial source/drain regions 62U may remain separated after the epitaxy process or may be merged.

After the upper epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for the second CESL 70 and the second ILD 72, and performing a planarization process to remove the excess portion of the corresponding layers. After the planarization process, top surfaces of the second ILD 72, the gate spacers 44, and the masks 86 (if present) or the dummy gates 84 are substantially coplanar (within process variations). Accordingly, the top surfaces of the mask layer 40 (if present) or the dummy gate layers 38 are exposed through the second ILD 124. In the illustrated embodiment, the mask layer 40 remain after the removal process. In other embodiments, the mask layer 40 are removed such that the top surfaces of the dummy gate layers 38 are exposed through the first ILD 68.

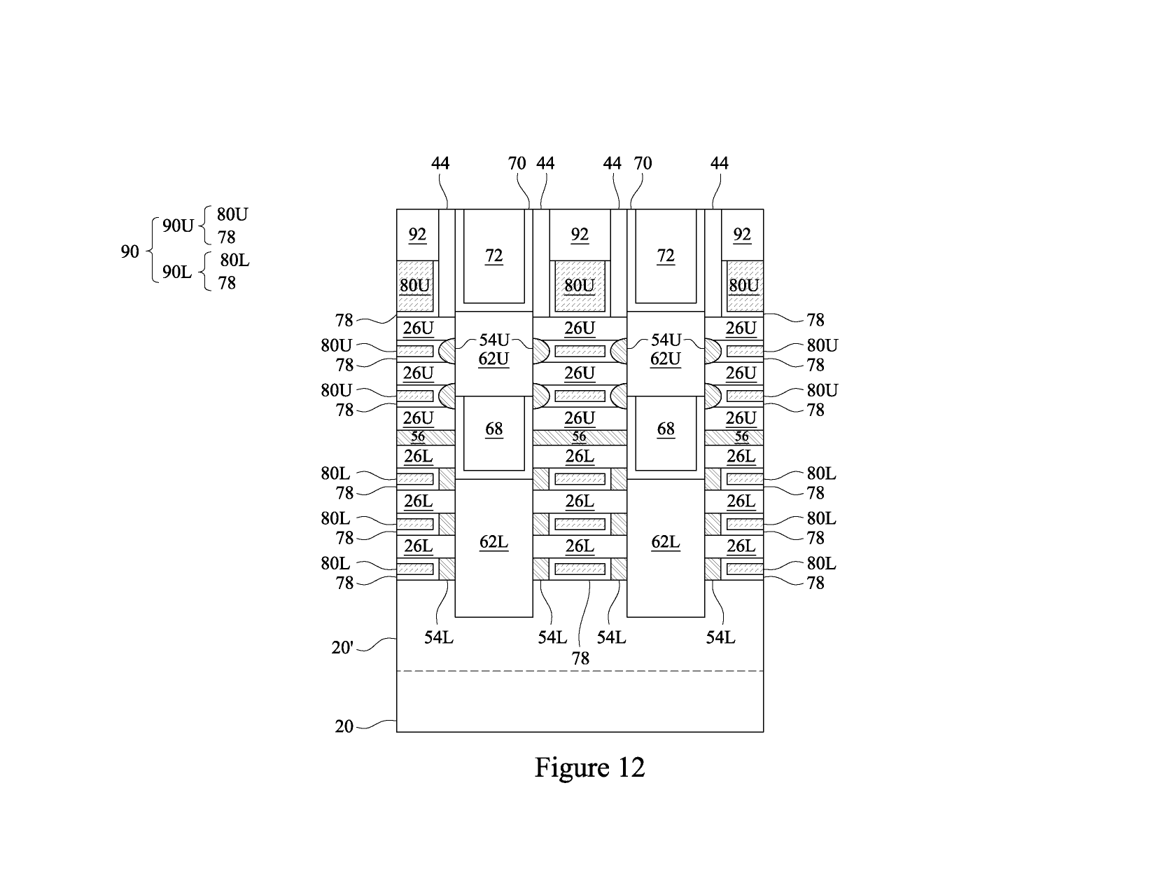

FIG. 12 illustrates a gate replacement process to replace the dummy gate stacks 42 and the dummy nanostructures 24A with gate structures 90. The gate replacement process includes first removing the dummy gate stacks 42 and the remaining portions of the sacrificial layers 32 and the dummy nanostructures 24A. The dummy gate stacks 42 are removed by one or more suitable etching processes. The remaining portions of the sacrificial layers 32 and the dummy nanostructures 24A are then removed by additional suitable etching processes. The remaining portions of the sacrificial layers 32 may be removed by a drying etching process using etchant(s), such as hydrofluoric acid, ammonia, and/or the like. The remaining portions of the dummy nanostructures 24A may be removed by a wet etching process using etchant(s), such as tetramethylammonium hydroxide, ammonium hydroxide, and/or the like. The semiconductor nanostructures 26 may remain intact during the etching processes. The corresponding strain of the stress the sacrificial layers 32 may induce in the upper semiconductor nanostructures 26U and the corresponding strain of the stress the dummy nanostructures 24A may induce in the lower semiconductor nanostructures 26L described above may remain in the upper semiconductor nanostructures 26U and the lower semiconductor nanostructures 26L after the sacrificial layers 32 and the dummy nanostructures 24A are removed. As a result, the overall performance of the stacking transistor may be improved.

Then, gate dielectrics 78 are deposited in the recesses between the gate spacers 44 and on the exposed semiconductor nanostructures 26. The gate dielectrics 78 are conformally formed on the exposed surfaces of the recesses (the removed dummy gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the semiconductor fins 20'; on the top surfaces, the sidewalls, and the bottom surfaces of the semiconductor nanostructures 26; and on the sidewalls of the inner spacers 54. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered upper gate electrodes 80U are illustrated, the upper gate electrodes 80U may include any number of work function tuning layers, any number of barrier layers, any number of glue layers, and a fill material.

Additionally, a removal process is performed to level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). The upper gate structures 90U may have concave sidewalls in contact with the convex inner sidewalls of the upper inner spacers 54U. The sidewalls of the upper gate structures 90U may have a third curvature. The lower gate structures 90L may have substantially straight sidewalls in contact with the substantially straight inner sidewalls of the lower inner spacers 54L or curved sidewalls in contact with the curved inner sidewalls of the lower inner spacers 54L. The sidewalls of the lower gate structures 90L may have a fourth curvature smaller than the third curvature of the sidewalls of the upper gate structures 90U. Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20'.

As also shown in FIG. 12, gate masks 92 are formed over the dummy gate stacks 42. The formation process may include recessing gate structures 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72.

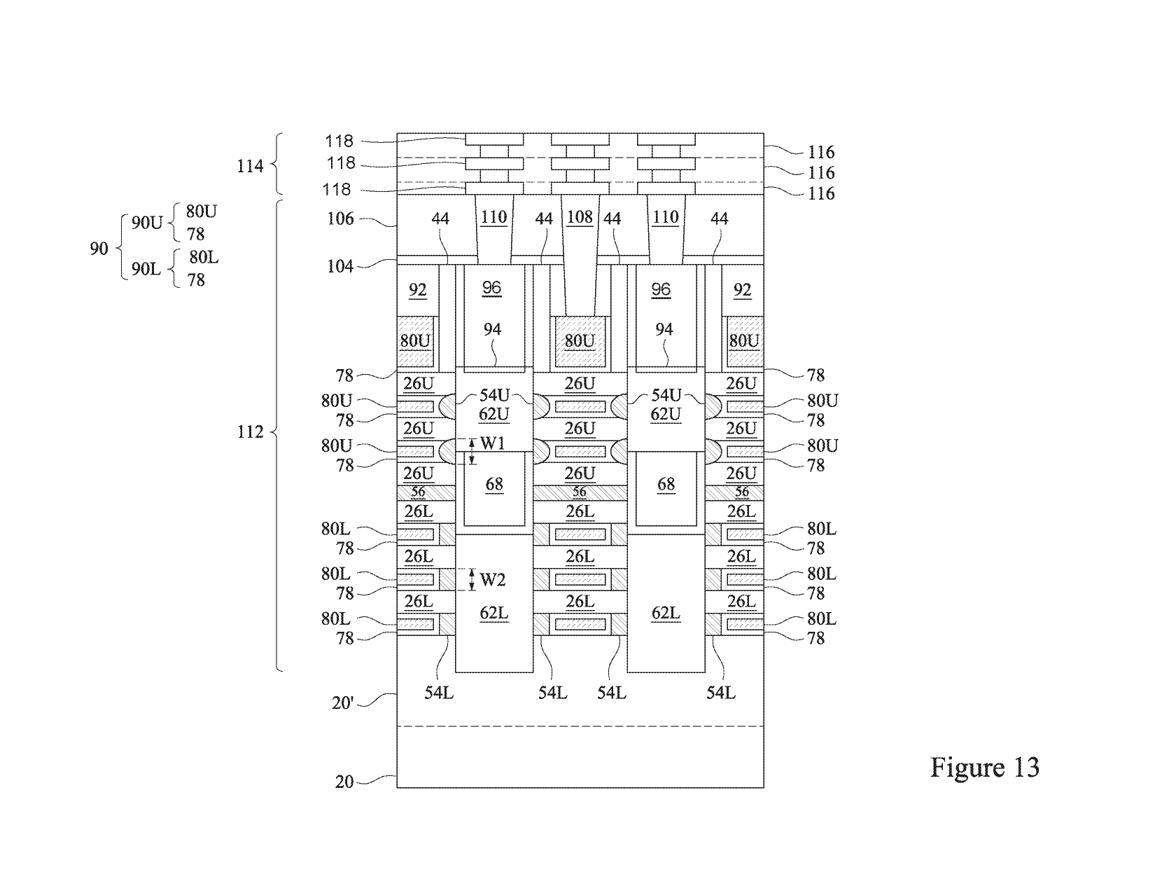

In FIG. 13, metal-semiconductor alloy regions 94 and source/drain contacts 96 are formed through the second ILD 72 to electrically couple to the upper epitaxial source/drain regions 62U and/or the lower epitaxial source/drain regions 62L. As an example to form the source/drain contacts 96, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the source/drain contacts 96 in the openings. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

An ESL 104 and a third ILD 106 are then formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the device layer 112. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate structures 90L and the lower epitaxial source/drain regions 62L may be made through a backside of the device layer 112 (e.g., a side opposite to the front-side interconnect structure 114).

The embodiments of the present disclosure have some advantageous features. By forming the sacrificial layers 32 on the upper semiconductor nanostructures 26U and forming the dummy nanostructures 24A on the lower semiconductor nanostructures 26L, different stress (and the corresponding strain) may be induced in the upper semiconductor nanostructures 26U and in the lower semiconductor nanostructures 26L. As a result, the overall performance of the stacking transistor including the upper semiconductor nanostructures 26U and the lower semiconductor nanostructures 26L may be improved.

In an embodiment, a semiconductor device includes a first nanostructure; a first gate structure wrapping around the first nanostructure; a first inner spacer on the first nanostructure and the first gate structure; a first source/drain region on the first nanostructure and the first inner spacer, wherein the first inner spacer has a first outer sidewall with a first width; a second nanostructure underneath the first nanostructure; a second gate structure wrapping around the second nanostructure; a second inner spacer on the second nanostructure and the second gate structure; and a second source/drain region on the second nanostructure and the second inner spacer, wherein the second inner spacer has a second outer sidewall with a second width smaller than the first width. In an embodiment, the first source/drain region includes a first dopant of a first conductivity type and, wherein the second source/drain region includes a second dopant of a second conductivity type different from the first conductivity type. In an embodiment, the first source/drain region is separated from the second source/drain region by a dielectric layer. In an embodiment, the semiconductor further includes an isolation layer between the first nanostructure and the second nanostructure. In an embodiment, the first inner spacer, the second inner spacer, and the isolation layer include a same dielectric material. In an embodiment, the first nanostructure and the second nanostructure include a same semiconductor material. In an embodiment, the first inner spacer has a first inner sidewall with a first curvature, wherein the second inner spacer has a second inner sidewall with a second curvature smaller than the first curvature.

In an embodiment, a method of forming a semiconductor device includes forming a first semiconductor nanostructure and a first dummy nanostructure on the first semiconductor nanostructure; forming a second semiconductor nanostructure underneath the first semiconductor nanostructure and a second dummy nanostructure on the second semiconductor nanostructure; forming a first dielectric layer, wherein sidewalls of the second dummy nanostructure are covered by the first dielectric layer and sidewalls of the first dummy nanostructure remain exposed after forming the first dielectric layer; removing the first dummy nanostructure to form a first opening, wherein the second dummy nanostructure remains intact after removing the first dummy nanostructure; removing the first dielectric layer to expose the sidewalls of the second dummy nanostructure; and forming a first sacrificial layer in the first opening. In an embodiment, the method includes recessing the second dummy nanostructure by an etching process; and forming a first inner spacer on the first sacrificial layer and forming a second inner spacer on the second dummy nanostructure by a disposition process. In an embodiment, the first inner spacer has first sidewall in contact with the first sacrificial layer, wherein the first sidewall has a first curvature, wherein the second inner spacer has second sidewall in contact with the second dummy nanostructure, and wherein the second sidewall has a second curvature smaller than the first curvature. In an embodiment, the method includes replacing the first sacrificial layer by a first gate structure and replacing the second dummy nanostructure by a second gate structure. In an embodiment, the first sacrificial layer and the second dummy nanostructure include different materials. In an embodiment, the method includes forming a first source/drain region on the first semiconductor nanostructure, wherein the first source/drain region includes a first dopant of a first conductivity type; and forming a second source/drain region on the second semiconductor nanostructure, wherein the second source/drain region includes a second dopant of a second conductivity type different from the first conductivity type. In an embodiment, forming the first dielectric layer includes performing a flowable chemical vapor deposition (FCVD) process, and wherein the FCVD process includes a deposition step, a curing step, and an annealing step.

In an embodiment, a method of forming a semiconductor device includes forming a stack of nanostructures over a substrate, wherein the stack of nanostructure includes a first semiconductor nanostructure, a first dummy nanostructure over the first semiconductor nanostructure, a second semiconductor nanostructure over the first dummy nanostructure, and a second dummy nanostructure over the second semiconductor nanostructure; replacing the second dummy nanostructure by a sacrificial layer, wherein the first dummy nanostructure remains intact after replacing the second dummy nanostructure; partially removing the first dummy nanostructure; forming a first inner spacer on the first dummy nanostructure and forming a second inner spacer on the sacrificial layer; and replacing the first dummy nanostructure by a first gate structure and replacing the sacrificial layer by a second gate structure. In an embodiment, the method includes forming a first dielectric layer, wherein sidewalls of the first dummy nanostructure are covered by the first dielectric layer and sidewalls of the second dummy nanostructure are free of the first dielectric layer; and removing the first dielectric layer before replacing the second dummy nanostructure by the sacrificial layer. In an embodiment, the first dummy nanostructure induces tensile stress and strain in the first semiconductor nanostructure, and wherein the sacrificial layer induces compressive stress and strain in the second semiconductor nanostructure. In an embodiment, the first dummy nanostructure induces compressive stress and strain in the first semiconductor nanostructure, and wherein the sacrificial layer induces tensile stress and strain in the second semiconductor nanostructure. In an embodiment, the method includes forming a first source/drain region on the first semiconductor nanostructure and the first inner spacer, and wherein the first source/drain region is doped with a first dopant; forming a second dielectric layer over the first source/drain region; and forming a second source/drain region on the second semiconductor nanostructure and the second inner spacer, wherein the second source/drain region is over the second dielectric layer, wherein the second source/drain region is doped with a second dopant, and wherein the first dopant and the second dopant are of opposite conductivity types. In an embodiment, the first inner spacer includes a first sidewall in contact with the first source/drain region, wherein the first sidewall has a first width, wherein the second inner spacer includes a second sidewall in contact with the second source/drain region, wherein the second sidewall has a second width larger than the first width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first semiconductor nanostructure;
a first gate structure wrapping around the first semiconductor nanostructure, wherein the first gate structure has a first sidewall with a first curvature;
a first source/drain region on the first semiconductor nanostructure;
a second semiconductor nanostructure underneath the first semiconductor nanostructure;
a second gate structure wrapping around the second semiconductor nanostructure, wherein the second gate structure has a second sidewall with a second curvature smaller than the first curvature; and
a second source/drain region on the second semiconductor nanostructure.

2. The semiconductor device of claim 1, wherein the first sidewall of the first gate structure is concave.

3. The semiconductor device of claim 2, further comprising a first inner spacer between the first gate structure and the first source/drain region, wherein the first inner spacer has a convex inner sidewall in contact with the concave first sidewall of the first gate structure.

4. The semiconductor device of claim 1, wherein the second sidewall of the second gate structure is substantially straight.

5. The semiconductor device of claim 1, wherein the first source/drain region comprises a first dopant of a first conductivity type, and wherein the second source/drain region comprises a second dopant of a second conductivity type different from the first conductivity type.

6. The semiconductor device of claim 1, further comprising a dielectric isolation layer between the first semiconductor nanostructure and the second semiconductor nanostructure.

7. The semiconductor device of claim 1, wherein the first gate structure comprises a first gate electrode comprising a first work function material, and wherein the second gate structure comprises a second gate electrode comprising a second work function material different from the first work function material.

8. A semiconductor device comprising:
a first semiconductor nanostructure having a first strain type;
a first gate structure wrapping around the first semiconductor nanostructure;
a first source/drain region on the first semiconductor nanostructure;
a second semiconductor nanostructure underneath the first semiconductor nanostructure, the second semiconductor nanostructure having a second strain type different from the first strain type;
a second gate structure wrapping around the second semiconductor nanostructure; and
a second source/drain region on the second semiconductor nanostructure.

9. The semiconductor device of claim 8, wherein the first strain type is compressive strain and the second strain type is tensile strain.

10. The semiconductor device of claim 8, wherein the first strain type is tensile strain and the second strain type is compressive strain.

11. The semiconductor device of claim 8, wherein the first source/drain region is a p-type source/drain region and the second source/drain region is an n-type source/drain region.

12. The semiconductor device of claim 8, further comprising:
a first inner spacer between the first gate structure and the first source/drain region, wherein the first inner spacer has a first outer sidewall with a first width; and
a second inner spacer between the second gate structure and the second source/drain region, wherein the second inner spacer has a second outer sidewall with a second width smaller than the first width.

13. The semiconductor device of claim 8, further comprising a dielectric isolation layer separating the first semiconductor nanostructure from the second semiconductor nanostructure.

14. A method comprising:
forming a multi-layer stack comprising a first semiconductor nanostructure, a first dummy nanostructure over the first semiconductor nanostructure, a second semiconductor nanostructure over the first dummy nanostructure, and a second dummy nanostructure over the second semiconductor nanostructure;
covering sidewalls of the first dummy nanostructure with a dielectric material while sidewalls of the second dummy nanostructure are free of the dielectric material;
removing the second dummy nanostructure while the first dummy nanostructure is protected by the dielectric material;
depositing a sacrificial material in spaces vacated by the second dummy nanostructure, wherein the sacrificial material is in contact with the second semiconductor nanostructure;
removing the dielectric material from the sidewalls of the first dummy nanostructure;
recessing the sacrificial material to form first recesses having concave surfaces and recessing the first dummy nanostructure to form second recesses; and
forming a first inner spacer in the first recesses and forming a second inner spacer in the second recesses, wherein the first inner spacer has a convex inner sidewall.

15. The method of claim 14, wherein the second inner spacer has a substantially straight inner sidewall.

16. The method of claim 14, wherein covering the sidewalls of the first dummy nanostructure with the dielectric material comprises performing a flowable chemical vapor deposition process.

17. The method of claim 14, wherein the sacrificial material induces a first stress in the second semiconductor nanostructure, and wherein the first dummy nanostructure induces a second stress in the first semiconductor nanostructure different from the first stress.

18. The method of claim 14, further comprising:
replacing the first dummy nanostructure with a first gate structure; and
replacing the sacrificial material with a second gate structure.

19. The method of claim 18, wherein the second gate structure has a concave sidewall in contact with the convex inner sidewall of the first inner spacer.

20. The method of claim 14, further comprising:
forming a first source/drain region on the first semiconductor nanostructure with a first dopant type; and
forming a second source/drain region on the second semiconductor nanostructure with a second dopant type opposite the first dopant type.
